(19) United States
(12) Patent Application Publication
(10) Pub. No.: US 2014/0130860 A1
(43) Pub. Date: May 15, 2014

(54) METHOD FOR FORMING ALUMINA FILM AND SOLAR CELL ELEMENT

(71) Applicants: Norikazu Ito, Moriyama-shi (JP); Akira Murao, Moriyama-shi (JP); Makoto Onodera, Ritto-shi (JP); Takeshi Ito, Higashiomi-shi (JP)

(72) Inventors: Norikazu Ito, Moriyama-shi (JP); Akira Murao, Moriyama-shi (JP); Makoto Onodera, Ritto-shi (JP); Takeshi Ito, Higashiomi-shi (JP)

(73) Assignee: KYOCERA Corporation, Kyoto-shi, Kyoto (JP)

(21) Appl. No.: 14/129,518

(22) PCT Filed: Jun. 27, 2012
(86) PCT No.: PCT/JP2012/066432

§ 371 Date: Dec. 26, 2013

(30) Foreign Application Priority Data
Jun. 30, 2011 (JP) 2011-145348

(51) Int. Cl. H01L 31/0232

(52) U.S. Cl. CPC H01L 31/02327
USPC 136/256; 438/72

(57) ABSTRACT

A solar cell element and a method for forming an alumina film are disclosed. The method comprises: preparing a substrate; supplying sources of an aluminum source material that contains aluminum atoms and an oxygen source material that contains oxygen atoms comprising H₂O and O₃ to the substrate; and forming an alumina film on the substrate.

### TECHNICAL FIELD

The present invention relates to a method for forming an alumina film by atomic layer deposition (ALD), and a solar cell element including an alumina film formed by the method.

### BACKGROUND ART

A solar cell element includes, for example, a silicon substrate with a passivation layer over a surface of the silicon substrate to reduce the recombination of minority carriers. It has been studied to use, as the passivation layer, an oxide film composed of silicon oxide, aluminum oxide (alumina) or the like, a nitride film composed of silicon nitride or the like (see, for example, Japanese Unexamined Patent Application Publication No. 2009-164544).

A method has also been studied for forming an alumina film to be used as the passivation layer of a solar cell element.

### SUMMARY OF INVENTION

### Technical Problem

However, a solar cell element including a passivation layer according to a related-art method for forming an alumina film has not sufficiently been improved to contribute to power generation efficiency. Accordingly, the industry desires a method for forming a suitable alumina film, and a solar cell element in which the recombination of minority carriers is reduced and whose output power characteristics have been enhanced.

### Solution to Problem

In order to solve the above-described disadvantage, a method for forming an alumina film according to an embodiment of the present invention includes: a preparation step of preparing a substrate; and a film-forming step of forming an alumina film by atomic layer deposition by supplying an aluminum source material containing aluminum atoms and an oxygen source material containing oxygen atoms to the substrate, and in the film-forming step, H₂O and O₃ are used as the oxygen source material.

Also, a solar cell element according to an embodiment of the invention includes an alumina film formed by the above-described method for forming an alumina film.

### Advantageous Effects of Invention

According to the method for forming an alumina film and the solar cell element, for example, the solar cell element that exhibits a high open-circuit voltage and good output power characteristics is provided.

### BRIEF DESCRIPTION OF DRAWINGS

FIG. 1 is a schematic sectional view illustrating an exemplary ALD apparatus used in an alumina film forming method according to an embodiment of the present invention.

FIG. 2 is a schematic plan view illustrating an exemplary solar cell element according to an embodiment of the present invention, viewed from a first surface side.

FIG. 3 is a schematic plan view illustrating an exemplary solar cell element according to the embodiment of the present invention element, viewed from a second surface side.

FIG. 4 is a schematic sectional view illustrating an exemplary solar cell element according to the embodiment of the present invention, taken along line A-A in FIG. 2.

FIG. 5 is a schematic sectional view illustrating an exemplary solar cell element according to an embodiment of the present invention, different from the solar cell element illustrated in FIG. 4, taken along a line corresponding to line A-A in FIG. 2.

FIG. 6 is a schematic plan view illustrating an exemplary solar cell element according to an embodiment of the present invention, different from the solar cell element illustrated in FIG. 3, viewed from a second surface side.

FIG. 7 is a schematic plan view illustrating an exemplary solar cell element according to an embodiment of the present invention, different from the solar cell element illustrated in FIG. 6, viewed from a second surface side.

FIG. 8 is a fragmentary enlarged schematic sectional view of a solar cell module according to an embodiment of the present invention.

FIG. 9 is a schematic plan view of a solar cell module according to an embodiment of the present invention, viewed from a first surface side.

FIG. 10 is a fragmentary enlarged schematic sectional view of a solar cell module according to an embodiment of the present invention, different from the solar cell module illustrated in FIG. 8.

### DESCRIPTION OF EMBODIMENTS

A method for forming an alumina film according to an embodiment of the invention and a solar cell element including an alumina film formed by this method will be described with reference to the drawings. Since the drawings illustrate schematic structures, actual dimensional proportions and positional relationships among components or members may be different from those illustrated in the drawings.

### <ALD Apparatus>

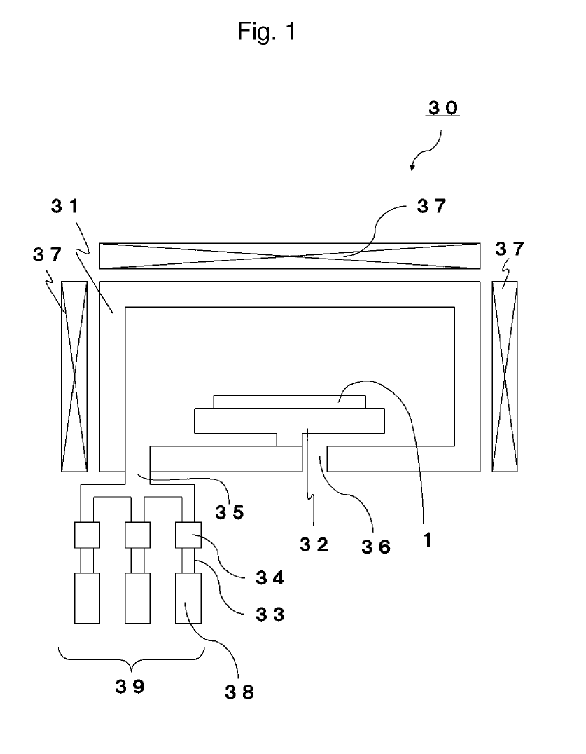

An ALD apparatus to be used for forming an alumina film on a substrate by atomic layer deposition will be described with reference to FIG. 1.

As illustrated in FIG. 1, the ALD apparatus 30 includes a chamber 31, a substrate mounting member 32, within the chamber 31, on which a substrate 1 such as a semiconductor substrate 1 is placed, a gas introduction mechanism 39 that introduces gases into the chamber 31, and an gas exhaust mechanism including an exhaust portion 36 through which the gases are discharged from the chamber 31. The gas introduction mechanism 39 is disposed outside the chamber 31 and includes introduction portions 33 through which gases are introduced, controllers 34 that control the supply of gases, and a supply portion 35 connected to the introduction portions 33 and disposed in the chamber 31, through which the gases are supplied to the chamber 31.

The chamber 31 has a function of offering a reaction space for forming an alumina film on the semiconductor substrate 1 and is a vacuum container having the reaction space that is defined at least by an upper wall, a side wall and a bottom wall and can be evacuated. The chamber 31 can be evacuated through the exhaust portion 36 connected to a vacuum pump (not illustrated) or the like. The chamber 31 may be composed of a metal member, such as stainless steel or aluminum.

The substrate mounting member 32 has the function of placing a substrate to be worked thereon. The substrate mounting member 32 may include therein, for example, a heater that controls the temperature of the semiconductor substrate 1. In this instance, the substrate mounting member 32 can function as a temperature control mechanism. Thus, the temperature of the semiconductor substrate 1 can be controlled to, for example, 100 to 400° C., more preferably 150 to 300° C. The substrate mounting member 32 may be composed of a metal material, such as stainless steel or aluminum.

The introduction portions 33 each have the function of introducing gases to the chamber 31. One ends of the introduction portions 33 are connected to gas cylinders 38 containing different gases, and the other ends are connected to the supply portion 35. Each introduction portion 33 is provided with a controller 34 including a mass flow meter or the like at an intermediate position thereof. The controllers 34 appropriately control gases. Also, the supply portion 35 allows gases to be delivered to the inside of the chamber 31 at predetermined flow rates. The pressure in the chamber 31 can be controlled to a predetermined level by appropriately adjusting the amounts of gases supplied and discharged.

The ALD apparatus 30 may include a heating portion 37 that heats the chamber 31. Thus, the temperature in the chamber 31 can be controlled. The heating portion 37 may be, for example, a resistance heater.

### <Method for Forming Alumina Film>

A method for forming an alumina film according to an embodiment of the present invention will be described. A method for forming an alumina film to be used as the passivation layer of a solar cell element including a silicon substrate will be described by way of example.

The method for forming an alumina film of an embodiment of the present invention basically includes the preparation step of preparing a substrate, and the film-forming step of forming an alumina film on the substrate by an ALD process using an aluminum source material containing aluminum atoms and an oxygen source material containing oxygen atoms. In the film-forming step, H₂O and O₃ are used as the oxygen source material.

More specifically, first, a semiconductor substrate 1, such as a silicon substrate, may be prepared. Then, the semiconductor substrate 1 is transported into the chamber 31 of the ALD apparatus 30 illustrated in FIG. 1 and placed on the substrate mounting member 32. The temperature of the semiconductor substrate 1 is controlled to a predetermined temperature with the heater in the substrate mounting member 32 or the heating portion 37, and the pressure in the chamber 31 is controlled to a predetermined pressure by controlling the amounts of gases supplied and discharged. The temperature of the semiconductor substrate 1 may be controlled, for example, to 100 to 400° C., more preferably 150 to 300° C. Also, the pressure in the chamber 31 can be controlled, for example, to 10 to 1000 Pa.

Subsequently, the aluminum source material containing aluminum atoms is evaporated, and the gas of the aluminum source material is supplied to the chamber 31 for a period of 0.015 to 1 second with a carrier gas such as argon or nitrogen gas so that the surface of the semiconductor substrate 1 adsorbs the aluminum source material (Step A). The aluminum source material may be, for example, trimethylaluminum, triethylaluminum, aluminum alkoxide, or trichloroaluminum. In the following description, trimethylaluminum is used as the aluminum source material.

Subsequently, an inert gas such as nitrogen gas is introduced as a purge gas into the chamber 31 for a period of 5 to 30 seconds to remove the aluminum source material from the reaction space and remove all the aluminum source material adsorbed to the surface of the substrate 1 except the component adsorbed at the atomic level (Step B).

Subsequently, the oxygen source material is supplied into the chamber 31, optionally with a carrier gas such as argon or nitrogen gas, for a period of 0.015 to 1 second. Thus the alkyl group, or CH₃, of trimethylaluminum as the aluminum source material is removed in the form of CH₄ from the surface of the semiconductor substrate 1, and a dangling bond of aluminum is oxidized to form an alumina layer at the atomic level (Step C).

Subsequently, an inert gas such as nitrogen gas is introduced as a purge gas into the chamber 31 for a period of 5 to 30 seconds to remove the oxygen source material from the reaction space and remove substances other than alumina present at the atomic level from the surface of the semiconductor substrate 1 (Step D). The substances at the surface of the semiconductor substrate 1 other than the alumina present at the atomic level include, for example, the oxygen source material, which has not been involved with the reaction in step C, or the like.

Thus an alumina film having a predetermined thickness is formed by repeating the operations from Step A to Step D to stack an alumina layer at the atomic level.

In the present embodiment, the film-forming step includes the first forming step of forming a first alumina film by supplying an aluminum source material and H₂O to the semiconductor substrate 1, and the second forming step of forming a second alumina film, after the first forming step, by supplying the aluminum source material and O₃ to the semiconductor substrate 1. More specifically, the first alumina film is formed by repeating the Steps A to D using H₂O as the oxygen source material (first forming step), and then the second alumina film is formed by repeating the Steps A to D using O₃ as the oxygen source material (second forming step).

The use of H₂O as the oxygen source material in the early stage of the film forming more facilitates the formation of hydroxy groups than the use of O₃. Accordingly, in the early stage of the film forming, the aluminum source material can be easily adsorbed to the surface of the semiconductor substrate 1 or the surface of the film. Consequently, dangling bonds at the surface of the semiconductor substrate 1 are reduced, and thus the interface between the semiconductor substrate 1 and the alumina film is brought into good condition.

On the other hand, by using O₃ as the oxygen source material in the late stage of the film forming, contamination of the film with a large amount of carbon impurities, which are derived from CH₄ formed in Step C when H₂O is used as the oxygen source material, can be reduced because O₃ has a nature of easily decomposing CH₄. In addition, by using O₃ as the oxygen source material in the late stage of the film forming, an alumina film having a high negative fixed charge can be formed for reasons that are unknown. Thus, an alumina film that is suitable as a passivation layer in which surface recombination has been reduced can be formed, and a solar cell element can be provided which exhibits a high open-circuit voltage and good output power characteristics.

When the first alumina film formed in the first forming step has a first thickness, the second alumina film formed on the first alumina film in the second forming step preferably has a second thickness larger than or equal to the first thickness. Thus, carbon impurities can be further reduced from the alumina film, and the alumina film can have a high negative fixed charge. For example, the first thickness of the first alumina film is about 0.1 to 5 nm, and the second thickness of the second alumina film is about 5 to 50 nm.

In another embodiment, the film-forming step may use a mixed gas of H₂O and O₃ as the oxygen source material. Even in such an embodiment, the alumina film has an interface in good condition with the semiconductor substrate 1, and the contamination of the alumina film with carbon impurities can be reduced.

In this embodiment, the third forming step of forming a third alumina film using a first mixed gas and the forth forming step of forming a fourth alumina film on the third alumina film using a second mixed gas may be performed instead of the first forming step and the second forming step. The first mixed gas contains H₂O and O₃ in a mass ratio R. The mass ratio is defined by dividing the mass of H₂O by the mass of O₃ (that is mass of H₂O/mass of O₃). The mass ratio R of the first mixed gas is a first ratio R1. The fourth forming step is performed after the third forming step using the second mixed gas containing H₂O and O₃ in a mass ratio R (mass of H₂O/mass of O₃) that is a second ratio R2 lower than the first ratio R1.

More specifically, the third alumina film is formed by repeating the Steps A to D using the first mixed gas having a mass ratio R that is the first ratio R1 as the oxygen source material (third forming step), and then the fourth alumina film is formed by repeating the Steps A to D using the second mixed gas having a mass ratio R that is the second ratio R2 as the oxygen source material (fourth forming step). Thus, H₂O rather than O₃ is mainly used as the oxygen source material in the early stage of the film forming, and consequently, the interface between the substrate and the alumina film in the early stage can be brought into good condition. In addition, O₃ rather than H₂O is mainly used as the oxygen source material in the late stage of the film forming. Consequently, contamination of the alumina film with carbon impurities can be reduced, and the resulting alumina film can have a high fixed charge. Thus, the alumina film can be suitably used as a passivation layer in which surface recombination has been reduced, and can provide a solar cell element having a high open-circuit voltage and good output power characteristics. For example, the first ratio R1 may be 1 or more, and the second ratio R2 may be less than 1.

If a mixed gas of H₂O and O₃ is used as the oxygen source material in the film-forming step, the mass ratio R of H₂O to O₃ in the mixed gas may be gradually reduced. In this case, this may be achieved by any of the following techniques in which a film-forming process including Steps A to D is defined as one cycle.

In a first technique, for example, the mass ratio R may be reduced cycle by cycle consecutively.

In a second technique, for example, the mass ratio R may be reduced in stages such that an alumina film is formed 1 to 10 cycles with a constant mass ratio R, and is then further formed 11 to 20 cycles with a mass ratio R reduced from the foregoing mass ratio R for 1 to 10 cycles.

In a third technique, for example, an alumina film may be formed by repeating the process of Steps A to D using only H₂O as the oxygen source material, subsequently repeating the process of Steps A to D while the mass ratio of O₃ in the oxygen source material is gradually increased, and then repeating the process of Steps A to D using only O₃ as the oxygen source material. In other words, this technique includes, between the first forming step and the second forming step, a step in an intermediate stage in which the above-described relationship of the mass ratio R is satisfied.

Preferably, a pretreatment step may be performed, before the film-forming process, to form hydroxy groups at the surface of the semiconductor substrate 1 by supplying H₂O to the inside of the chamber 31 for a period of 0.015 to 5 seconds. After the pretreatment step is thus performed, the chamber 31 is purged with an inert gas such as nitrogen gas, and Step A of adsorbing the aluminum source material containing aluminum atoms to the semiconductor substrate 1 is performed. Thus, the state of the interface between the semiconductor substrate 1 and the alumina film can be brought into a good condition, and the surface recombination rate can be further reduced.

Preferably, a polycrystalline silicon substrate is prepared as the semiconductor substrate 1. Polycrystalline silicon substrates contain more grain boundaries and crystal defects than single crystal silicon substrates. According to the above-described method for forming an alumina film, dangling bonds at the surface of such a polycrystalline silicon substrate containing many grain boundaries and crystal defects can be more easily passivated, and thus an alumina film is obtained in which the surface recombination rate of the alumina film is further reduced.

The oxygen source material to be used in Step C may contain hydrogen in addition to the above mentioned oxygen source material. Such oxygen source material helps the alumina film contain hydrogen, consequently enhancing the effect of hydrogen passivation.

### <Solar Cell Element>

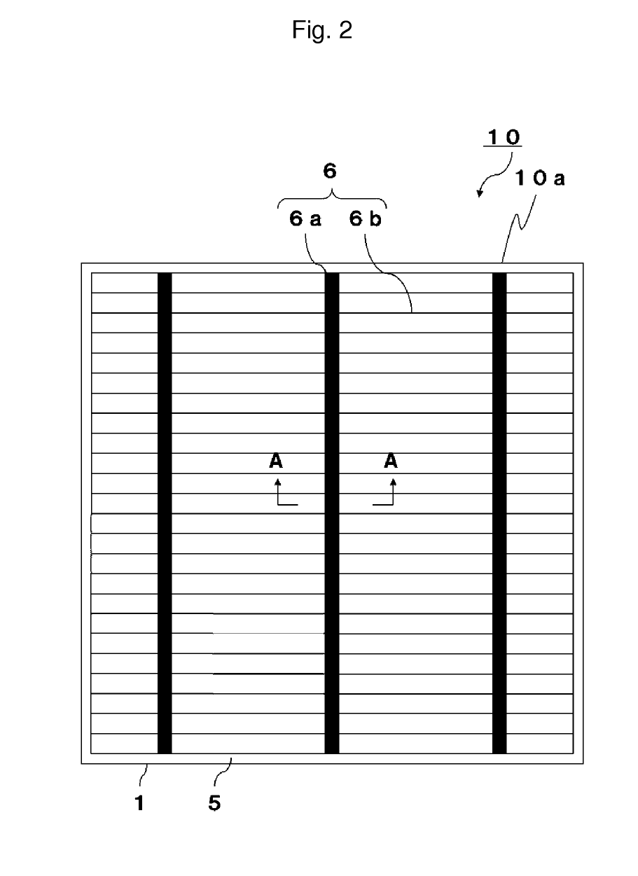

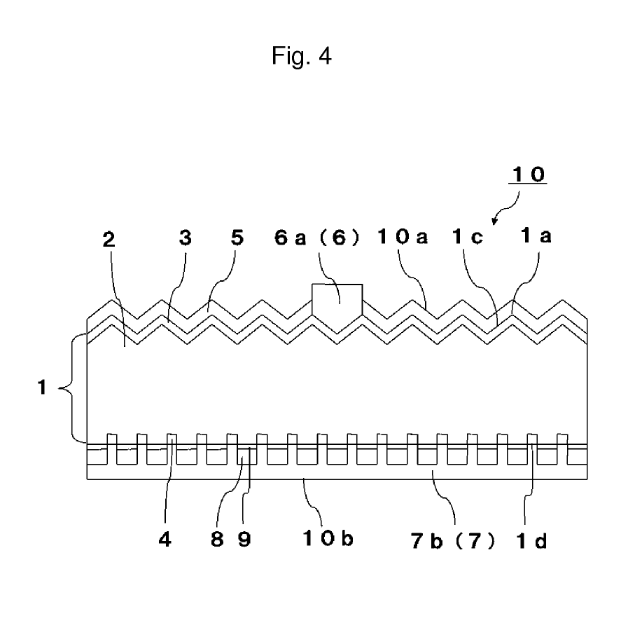

The entirety or a part of the solar cell element 10 of an embodiment of the present invention is illustrated in FIGS. 2 to 4. As illustrated in FIGS. 2 to 4, the solar cell element 10 has a first surface 10a acting as a light-receiving surface (upper surface in FIG. 4) on which light is incident, and a second surface 10b that is the rear surface opposite the first surface 10a and acts as a non-light-receiving surface (lower surface in FIG. 4). The solar cell element 10 includes a semiconductor substrate 1 that is a plate-like polycrystalline silicon substrate.

As illustrated in FIG. 4, the semiconductor substrate 1 includes, for example, a first semiconductor layer (p-type semiconductor layer) 2 that is a semiconductor layer having a conductivity type, and a second semiconductor layer disposed on the first surface 10a side of the first semiconductor layer 2 and having an opposite conductivity type. The solar cell element 10 further includes a passivation layer (alumina film) 8 mainly composed of amorphous alumina, disposed on the second surface 10b side of the first semiconductor layer 2.

More specifically, in the solar cell element 10, an antireflection layer 5 and a first electrode 6 are disposed on the first surface 10a side of the semiconductor substrate 1 (on the first semiconductor layer 2 and the second semiconductor layer 3), and a third semiconductor layer 4 and the passivation layer 8 are disposed on the second surface 10b side of the first semiconductor layer 2, with a second electrode 7 thereon.

As described above, the semiconductor substrate 1 includes the first semiconductor layer 2, and the second semiconductor layer 3 on the first surface 10a side of the semiconductor layer 2.

As described above, a p-type semiconductor plate can be used as the first semiconductor layer 2. The semiconductor used as the first semiconductor layer 2 may be a single crystal silicon substrate or a polycrystalline silicon substrate. The thickness of the first semiconductor layer 2 may be, for example, 250 μm or less, or 150 μm or less, and the shape of the first semiconductor layer 2 may be, but not limited to, quadrilateral in plan view from the viewpoint of manufacture. When the first semiconductor layer 2 has the p-type conductivity, for example, boron or gallium can be used as a dopant element.

In the present embodiment, the second semiconductor layer 3 will form a pn junction with the first semiconductor layer 2. The second semiconductor layer 3 has a conductivity type opposite to the first semiconductor layer 2, that is, has n-type conductivity, and is disposed on the first surface 10a side of the first semiconductor layer 2. If the first semiconductor layer 2 is a silicon substrate having p-type conductivity, the second semiconductor layer 3 can be formed by, for example, diffusing impurities, such as phosphorus, in the first surface 10a side of the silicon substrate.

As illustrated in FIG. 4, the semiconductor substrate 1 has a first concave-convex shape 1a at the first surface 1c side of the semiconductor substrate 1. The first concave-convex shape 1a has protrusions having a height of 0.1 to 10 μm and a width of about 0.1 to 20 μm. The first concave-convex shape 1a in sectional view is not limited to the shape of pyramids having angles as illustrated in FIG. 4, and may have substantially spherical recesses.

“The height of the protrusions” mentioned above refers to the distance in sectional view, in the direction perpendicular to the base line passing through the bottoms of the recesses, between the base line and the top of the protrusions. Also, “the width of the protrusions” mentioned above refers to the distance in sectional view, in the direction parallel to the base line, between the top of two adjacent protrusions.

The antireflection layer 5 is intended to enhance light absorption, and is disposed on the first surface 10a side of the semiconductor substrate 1. More specifically, the antireflection layer 5 is disposed on the first surface 10a side of the second semiconductor layer 3. Also, the antireflection layer 5 is composed of, for example, a silicon nitride film, a titanium oxide film, a silicon oxide film, a magnesium oxide film, an indium tin oxide film, a tin oxide film, or a zinc oxide film. The thickness of the antireflection layer 5 may be appropriately selected according to the material and may be the thickness with which some incident light rays do not reflect. For example, the antireflection layer 5 has a refractive index of about 1.8 to 2.3 and a thickness of about 500 to 1200 Å. If the antireflection layer 5 is composed of a silicon nitride film, the antireflection layer 5 has the passivation effect.

The passivation layer 8 is disposed on the second surface 10b side of the semiconductor substrate 1. The passivation layer 8 mainly includes, for example, an amorphous alumina layer. With the above-described structure, a solar cell element having a high open-circuit voltage and good output power characteristics is obtained. It is assumed that in addition to the surface passivation effect, an amorphous alumina film formed using hydrogen is used, which allows a large part of the hydrogen contained in the alumina film to diffuse easily into the semiconductor substrate 1 and to terminate dangling bonds with the hydrogen, and the surface recombination of minority carriers to be reduced. In addition, since the alumina film has a negative fixed charge, the band around the interface of the p-type semiconductor substrate 1 is bent in the direction in which the number of minority carriers decreases at the interface, and thus the surface recombination of the minority carriers can be further reduced. The amorphous alumina film mentioned herein has a crystallization ratio of less than 50%. The crystallization ratio can be determined from the proportion of crystalline substances accounting for the region observed through a TEM (Transmission Electron Microscope).

Thickness of the passivation layer 8 can be, for example, about 30 to 1000 Å.

The solar cell element 10 may include a silicon oxide layer 9 between the first semiconductor layer 2 and the passivation layer 8. Thus, dangling bonds at the surface of the second surface 10b side of the semiconductor substrate 1 can be terminated, and the surface recombination of minority carriers can be reduced. Furthermore, such a structure can alleviate irregularity in the binding state of the passivation layer 8, which is caused depending on the binding state of silicon, as compared to the case where the passivation layer 8 is disposed directly on the silicon substrate. Thus, the passivation layer 8 can exhibit such high quality that the interface has few defects. Consequently, the passivation effect of the passivation layer 8 is enhanced, and accordingly, the solar cell element 10 can exhibit good output power characteristics. The silicon oxide layer 9 may be, for example, a silicon oxide film having a very small thickness of about 5 to 100 Å on the surface of the semiconductor substrate 1.

Also, the sheet resistance βs of the passivation layer 8 may be 20 to 80Ω per square. Since such a passivation layer 8 has a high negative fixed charge, the band around the interface is bent considerably in a direction in which the number of minority carriers is reduced at the interface. Consequently, surface recombination can be further reduced, and thus the solar cell element 10 can exhibit further enhanced output power characteristics.

The sheet resistance ρs of the passivation layer 8 can be measured by, for example, a four-terminal method. More specifically, for example, the sheet resistance ρs of the passivation layer 8 can be defined as the average of values measured at five points, in total, of middle and corners of the passivation layer 8 with a measurement probe brought into contact with each of the five points.

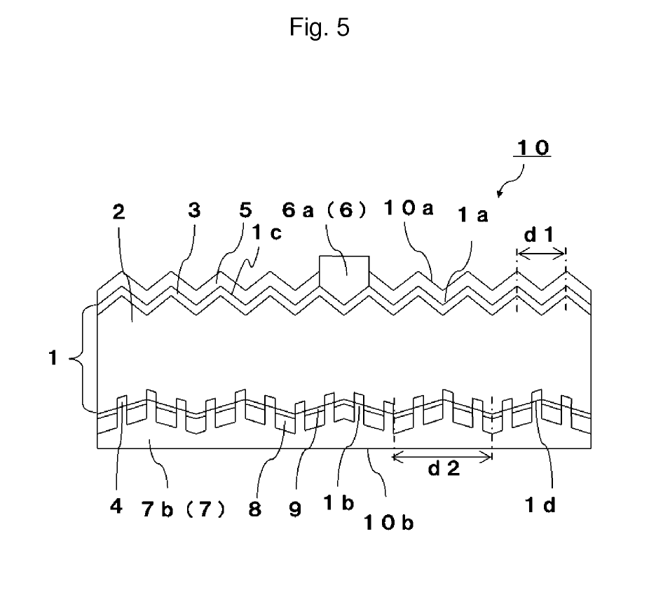

In another embodiment, the semiconductor substrate 1 may be provided with a second concave-convex shape 1b in a second surface 1d thereof that is the rear surface opposite the first main surface 1c thereof, as illustrated in FIG. 5. In this instance, the average distance d2 between the protrusions of the second concave-convex shape 1b in the second surface 1d side may be larger than the average distance d1 between the protrusions of the first concave-convex shape 1a in the first surface 1c side. The distance d1 or d2 between protrusions is defined as the average of distances between arbitrarily selected three or more protrusions.

By thus increasing the average distance d2 between the protrusions of the second concave-convex shape 1b, the amount of light having passed through the semiconductor substrate 1 and then reflected to the semiconductor substrate 1 can be increased. Also, since the surface area of the second surface 1d side is reduced as compared to the surface area of the first surface 1c side, the surface recombination of minority carriers can be further reduced. Consequently, the solar cell element 10 can exhibit further enhanced output power characteristics.

The third semiconductor layer 4 is disposed on the second surface 10b side of the semiconductor substrate 1, and has the same conductivity type as the first semiconductor layer 2, that is, p-type conductivity. The dopant concentration of the third semiconductor layer 4 is higher than the dopant concentration of the first semiconductor layer 2. More specifically, the third semiconductor layer 4 contains a dopant element with a concentration higher than that of the dopant element implanted to the first semiconductor layer 2 for having a conductivity type. The third semiconductor layer 4 has the function of minimizing the decrease in conversion efficiency resulting from the recombination of minority carriers in the semiconductor substrate 1 in the vicinity of the second surface 10b, and forms an internal electric field on the second surface 10b side of the semiconductor substrate 1. For example, the third semiconductor layer 4 may be formed by diffusing a dopant element, such as boron or aluminum, in the second surface 10b side of the semiconductor substrate 1. In this instance, the concentration of the dopant element in the third semiconductor layer 4 may be about 1×10¹⁸ to 5×10²¹ atoms/cm³. Preferably, the third semiconductor layer 4 is formed in the zone where the second electrode 7 is in contact with the semiconductor substrate 1, as described later.

The first electrode 6 is disposed on the first surface 10a side of the semiconductor substrate 1, and includes a first power extraction electrode 6a and a plurality of first linear collector electrodes 6b, as illustrated in FIG. 2. At least part of the first power extraction electrode 6a intersects the first collector electrodes 6b and is electrically connected to the first collector electrodes. The first power extraction electrode 6a has a width, in the short-length direction, of, for example, about 1.3 to 2.5 mm. The first collector electrodes 6b are linear in shape, and the width in the short-length direction of each first collector electrode 6b is smaller than the width in the short-length direction of the first power extraction electrode 6a. For example, the width in the short-length direction of the first collector electrode 6b is about 50 to 200 μm. The first collector electrodes 6b are arranged at intervals of about 1.5 to 3 mm. The first electrode 6 has a thickness of about 10 to 40 μm. The first electrode 6 can be formed by, for example, applying a conductive paste mainly containing silver in a predetermined pattern by screen printing or the like, and then firing the applied paste.

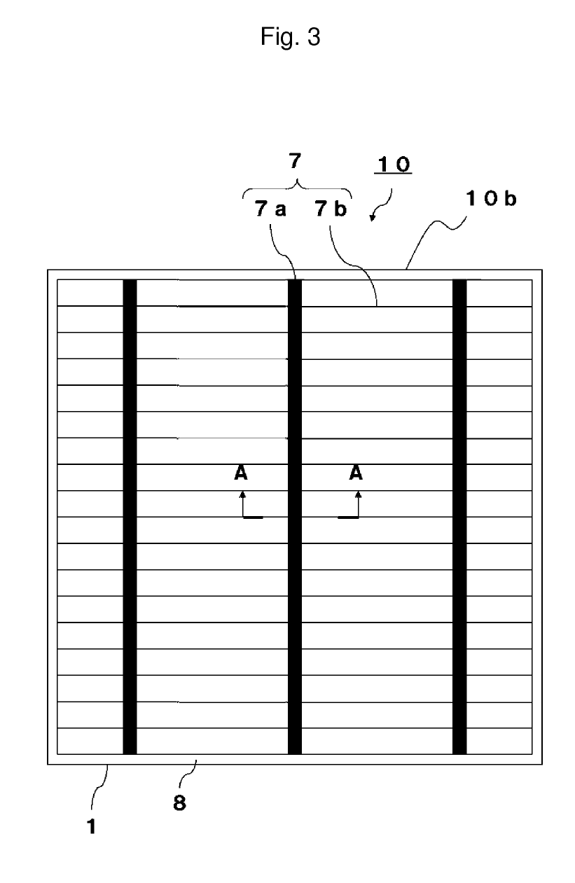

The second electrode 7 is disposed on the second surface 10b side of the semiconductor substrate 1, and may have the same structure as the first electrode 6. More specifically, the second electrode 7 includes a second power extraction electrode 7a and a plurality of second linear collector electrodes 7b, as illustrated in FIG. 3. At least part of the second power extraction electrode 7a intersects the second collector electrodes 7b and is electrically connected to the second collector electrodes 7b. The second power extraction electrode 7a has a width, in the short-length direction, of, for example, about 1.3 to 3 mm. The second collector electrodes 7b are linear in shape, and the width in the short-length direction of each second collector electrode 7b is smaller than the width in the short-length direction of the second power extraction electrode 7a. For example, the width in the short-length direction of the second collector electrode 7b is about 50 to 300 μm. The second collector electrodes 7b are arranged at intervals of about 1.5 to 3 mm. The second electrode 7 has a thickness of about 10 to 40 μm. The second electrode 7 can be formed by, for example, applying a conductive paste mainly containing silver in a predetermined pattern by screen printing or the like, and then firing the applied paste. In this instance, by forming the second electrode 7 with a width in the short-length direction larger than the first electrode 6, the series resistance of the second electrode 7 can be reduced, and thus, the output power characteristics can be enhanced.

The solar cell element 10 of the present embodiment may further include other layers at either the first surface 10a side or the second surface 10b side. For example, the solar cell element 10 may further include another crystalline alumina layer on the second surface 10b side of the passivation layer 8. In other words, the crystalline alumina layer may be disposed between the passivation layer 8 and the second electrode 7.

### <Method for Manufacturing Solar Cell Element>

A method for manufacturing the solar cell element 10 will be described in detail.

First, a substrate preparing step will be described in which a semiconductor substrate (polycrystalline silicon substrate) 1 including a first semiconductor layer (p-type semiconductor layer) 2 is prepared. The semiconductor substrate 1 is formed by, for example, a known casting method or the like. In the following description, a p-type polycrystalline silicon substrate is used as the semiconductor substrate 1.

First, an ingot of polycrystalline silicon is prepared by, for example, casting. Subsequently, the ingot is sliced to have a thickness of, for example, about 250 μm or less. Then, the surface of the semiconductor substrate 1 may be very slightly etched with NaOH, KOH, hydrofluoric acid, fluoronitric acid, or the like to remove a mechanically damaged or contaminated layer at the section of the semiconductor substrate 1.

Subsequently, a first concave-convex shape 1a is formed in the first surface 1c of the semiconductor substrate 1. The first concave-convex shape 1a may be formed by wet etching using an alkali solution such as NaOH or an acid solution such as fluoronitric acid, or by dry etching such as RIE. If a second concave-convex shape 1b is formed in the second surface 1d, the second concave-convex shape 1b can be formed in the same manner as the first concave-convex shape 1a. In this instance, the second concave-convex shape 1b is formed in at least the second surface 1d side of the semiconductor substrate 1 by wet etching, and then the first concave-convex shape 1a is formed in the first surface 1c side by dry etching. Thus, the average distance d2 between the protrusions of the second concave-convex shape 1b in the second surface 1d side becomes larger than the average distance d1 between the protrusions of the first concave-convex shape 1a in the first surface 1c side.

Subsequently, the first surface 1c of the semiconductor substrate 1 having the first concave-convex shape 1a formed in the above step is subjected to the step of forming a second semiconductor layer 3. More specifically, an n-type second semiconductor layer 3 is formed in the surface of the first surface 10a side of the semiconductor substrate 1 having the first concave-convex shape 1a.

The second semiconductor layer 3 is formed by using a thermal diffusion method in which a P₂O₅ paste is applied to the surface of the semiconductor substrate 1 and is then thermally diffused, a gas phase thermal diffusion method using phosphoryl chloride (POCl₃) gas as a diffusion source, or the like. The second semiconductor layer 3 is formed to have a depth of about 0.2 to 2 μm with a sheet resistance of about 40 to 200Ω per square. In the gas phase diffusion process, for example, a phosphate glass coating is formed over the surface of the semiconductor substrate 1 by heat-treating the semiconductor substrate 1 at a temperature of about 600 to 800° C. for about 5 to 30 minutes in an atmosphere containing a diffusion gas such as POCl₃. Then, the semiconductor substrate 1 is heat-treated at a high temperature of about 800 to 900° C. for about 10 to 40 minutes in an atmosphere of an inert gas such as argon or nitrogen. Thus, phosphorus diffuses into the semiconductor substrate 1 from the phosphate glass coating, thereby forming the second semiconductor layer 3 on the first surface 10a side of the semiconductor substrate 1.

If the second semiconductor layer 3 has been formed also on the second surface 10b side in the above-described step of forming the second semiconductor layer 3, the second semiconductor layer 3 at the second surface 10b side is removed by etching. Thus, the p-type conductivity region is exposed at the second surface 10b side. For example, only the second surface 10b side of the semiconductor substrate 1 is soaked in a fluoronitric acid solution to remove the second semiconductor layer 3 from the second surface 10b side. Then, phosphate glass, which has been attached to the surface (first surface 10a side) of the semiconductor substrate 1 when the second semiconductor layer 3 has been formed, is removed by etching.

Since the second semiconductor layer 3 on the second surface 10b side is thus removed with the phosphate glass left on the first surface 10a side, the phosphate glass can minimizes the removal of or damage to the second semiconductor layer 3 on the first surface 10a side.

Alternatively, in the step of forming the second semiconductor layer 3, the second surface 10b side is covered with a diffusion mask in advance, and then the second semiconductor layer 3 is formed by gas phase thermal diffusion or the like, followed by removing the diffusion mask. Such a process can also provide the same structure. Since the second semiconductor layer 3 is not formed on the second surface 10b side in this case, the removal of the second semiconductor layer 3 from the second surface 10b side can be omitted.

The process for forming the second semiconductor layer 3 is not limited to the above-described process. For example, an n-type hydrogenated amorphous silicon film or crystalline silicon film including a microcrystalline silicon film may be formed by a thin-film technique. An i-type silicon region may be formed between the first semiconductor layer 2 and the second semiconductor layer 3.

Thus, a polycrystalline silicon semiconductor substrate 1 having the first concave-convex shape 1a in the surface thereof is prepared which includes the second semiconductor layer 3, which is an n-type semiconductor layer, on the first surface 10a side, and the p-type first semiconductor layer 2 having the first concave-convex shape 1a in the surface thereof.

Subsequently, an antireflection layer 5 is formed over the second semiconductor layer 3 on the first surface 10a side of the semiconductor substrate 1. The antireflection layer 5 is formed by, for example, PECVD (plasma enhanced chemical vapor deposition), vapor deposition, sputtering or the like. If a silicon nitride antireflection layer 5 is formed by PECVD, for example, the antireflection layer 5 is formed by depositing plasma of a mixed gas of silane (SiH₄) and ammonia (NH₃) that is formed by glow discharge decomposition of the mixed gas diluted with nitrogen (N₂). The deposition chamber can be set at about 500° C. at this time.

Subsequently, a passivation layer 8 including an alumina film is formed on the second surface 10b side of the semiconductor substrate 1. The alumina film of the passivation layer 8 is formed by the method for forming an alumina film according to the above-described embodiment. The passivation 8 including an alumina film may also be formed on the side surface of the semiconductor substrate 1.

Subsequently, a first electrode 6 (first power extraction electrode 6a, first collector electrodes 6b), a third semiconductor layer 4, and a second electrode 7 (first layer 7a, second layer 7b) are formed as below.

First, the formation of the first electrode 6 will be described. The first electrode 6 is formed using a conductive paste containing a metal powder of, for example, silver (Ag), an organic vehicle, and a glass frit. The first electrode 6 is formed by applying the conductive paste to the first surface 10a side of the semiconductor substrate 1, and then firing the conductive paste at a temperature up to 600 to 800° C. for several tens of seconds to several tens of minutes. The application of the conductive paste can be performed by screen printing or any other technique. After the application, the solvent may be evaporated to dry at a predetermined temperature. The first electrode 6 includes the first power extraction electrode 6a and the first collector electrodes 6b. Screen printing allows the first extraction electrode 6a and first collector electrodes 6b to be formed in a single step.

Second, the formation of the third semiconductor layer 4 will be described. An aluminum paste containing a glass frit is applied directly in a predetermined region on the passivation layer 8. Then, the component of the applied paste is allowed to penetrate the passivation layer 8 to form the third semiconductor layer 4 on the second surface 10b side of the semiconductor substrate 1 by the fire-through technique of performing heat treatment at a temperature up to 600 to 800° C. In this step, an aluminum layer (not illustrated) is formed on the third semiconductor layer 4. The third semiconductor layer 4 is formed, for example, in a dotted manner at intervals of 200 μm to 1 mm within the region of the second surface 10b side where the second electrode 7 will be formed. The aluminum layer on the third semiconductor layer 4 may be removed before forming the second electrode 7, or may be used as the second electrode 7 without being removed.

Next, the second electrode 7 will be described. The second electrode 7 is formed using a conductive paste containing a metal powder of, for example, silver (Ag), an organic vehicle, and a glass frit. The second electrode 7 is formed by applying the conductive paste to the second surface 10b side of the semiconductor substrate 1, and then firing the conductive paste at a temperature up to 500 to 700° C. for several tens of seconds to several tens of minutes. The application of the conductive paste can be performed by screen printing or any other technique. After the application of the conductive paste, the solvent may be evaporated to dry at a predetermined temperature. The second electrode 7 includes the second power extraction electrode 7a and the second collector electrodes 7b. Screen printing allows the second extraction electrode 7a and second collector electrodes 7b to be formed in a single step.

Although, in the above description, the first electrode 6 and the second electrode 7 are formed by printing and firing a conductive paste, these electrodes may be formed by a thin-film forming technique such as vapor deposition or sputtering, or by plating.

The solar cell element 10 can be produced as above. Since the solar cell element 10 includes the passivation layer 8 of the above-described alumina film, the surface recombination rate of minority carriers is low, and accordingly, the solar cell element 10 exhibits a high open-circuit voltage and good output power characteristics.

### <Modification>

The present invention is not limited to the above-described embodiments, and various modifications and changes may be made.

For example, the third semiconductor layer 4 may be formed before forming the passivation layer 8. In this instance, boron or aluminum can be diffused in a predetermined region of the second surface 10b side before the step of forming the passivation layer 8. Boron can be diffused by thermal diffusion using boron tribromide (BBr₃) as a diffusion source, with the semiconductor substrate 1 heated to about 800 to 1100° C. The third semiconductor layer 4 may be a p-type hydrogenated amorphous silicon film or crystalline silicon film including a microcrystalline silicon film formed by a thin-film technique. Also, an i-type silicon region may be formed between the semiconductor substrate 1 and the third semiconductor layer 4.

The antireflection layer 5 and the passivation layer 8 may be formed in the reverse order of the order described above.

The semiconductor substrate 1 may be cleaned before forming the antireflection layer 3 and the passivation layer 8. The cleaning step may be performed by, for example, hydrofluoric acid treatment, RCA cleaning (a cleaning technique developed by an US company RCA, in which cleaning is performed using high-temperature, high-concentration sulfuric acid and hydrogen peroxide solution; dilute hydrofluoric acid (room temperature); ammonia water and hydrogen peroxide solution; or hydrochloric acid and hydrogen peroxide solution) followed by hydrofluoric acid treatment, or SPM (Sulfuric Acid/Hydrogen Peroxide/Water Mixture) cleaning followed by hydrofluoric acid treatment thereafter.

A silicon oxide layer 9 may be formed before forming the antireflection layer 5 and the passivation layer 8. The silicon oxide layer 9 may be formed to have a thickness of about 5 to 100 Å on the second surface 10b side of the semiconductor substrate 1 by nitric acid oxidation treating the semiconductor substrate 1 with a nitric acid solution or nitric acid vapor, after removing a naturally oxidized film due to hydrofluoric acid treatment from the semiconductor substrate 1. The silicon oxide layer 9 thus formed with a small thickness on the second surface 10b side can further enhance the passivation effect. More specifically, the silicon oxide layer 9 may be formed over the surface of the semiconductor substrate 1 by immersing the semiconductor substrate 1 in a heated nitric acid solution with a concentration of 60% by mass or more, or holding the semiconductor substrate 1 in nitric acid vapor generated by boiling a nitric acid solution with a concentration of 60% by mass or more. In this instance, the temperature of the nitric acid solution may be slightly lower than the boiling point, and, for example, 100° C. or higher. The treatment time can be appropriately set so that the silicon oxide layer 9 can have a predetermined thickness. Since nitric acid oxidation can be performed by a wet process at a much lower temperature than thermal oxidation, nitric acid oxidation can be performed immediately after the cleaning step, and thus the passivation layer 8 can be formed in a state where surface contamination has been reduced.

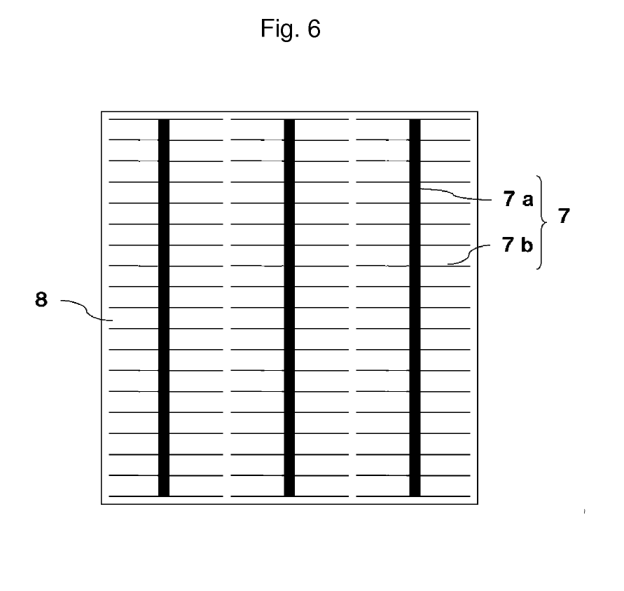

The shape of the contact region of the second electrode 7 and the semiconductor substrate 1 (third semiconductor layer 4) is not limited to the above-described dotted shape, and the contact region may be formed in lines over the entire region of the second collector electrodes 7b. Also, the shape of the second electrode 7 is not limited to the above-described grid shape. At least part of the second collector electrodes 7b may be removed, and each of the divided portions of the second collector electrodes 7b is connected to the second power extraction electrode 7a, as illustrated in FIG. 6.

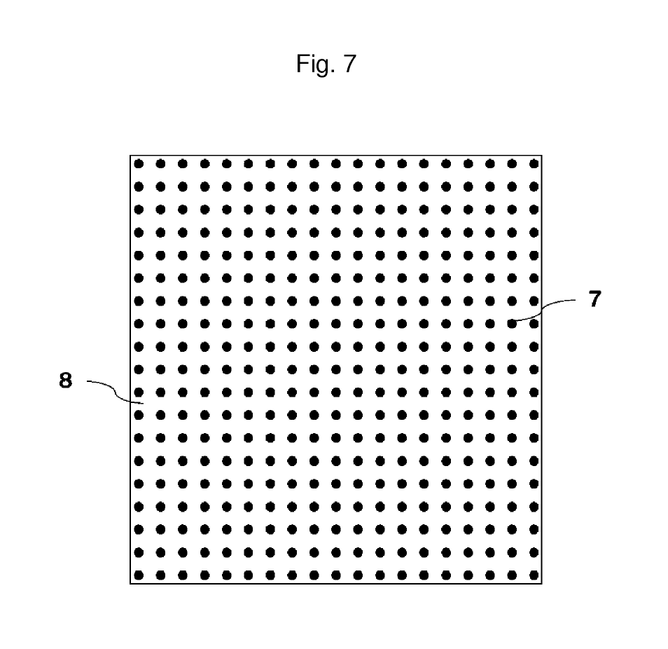

Alternatively, the second electrode 7 may be formed in a circular pattern as illustrated in FIG. 7. In this instance, when a plurality of solar cell elements 10 are connected, the second electrode 7 in such a circular pattern may be connected with a wiring member such as a conductive sheet. The second electrode 7 in a circular pattern can be connected to the conductive sheet with a conductive adhesive or a solder paste. Alternatively, the second electrode 7 may be formed over substantially the entire surface of the semiconductor substrate 1. The use of such a second electrode 7 increases the ratio of the light reflected and returning to the semiconductor substrate 1 to the light having passed through the semiconductor substrate 1 and the passivation layer 8. In this instance, the second electrode 7 may be composed of a metal having a high reflectance, such as silver.

In any step after the step of forming the passivation layer 8, annealing treatment may be performed using a gas containing hydrogen, thereby reducing the recombination rate at the rear surface (second surface 10b) of the semiconductor substrate 1.

If a solar cell element is produced using an n-type polycrystalline silicon substrate as the semiconductor substrate 1, the second semiconductor layer 3 has p-type conductivity. Accordingly, the passivation layer 8 of an alumina film can be formed on the first surface 10a side of the semiconductor substrate 1 to produce the effect expected from the above-described embodiment.

Although the present embodiment illustrates a single layer passivation layer 8 of an alumina film, the structure of the passivation layer 8 is not limited to this. For example, the passivation layer 8 may include a nitride film in addition to the alumina film. Such a structure can produce the above-described effect.

### <Solar Cell Module>

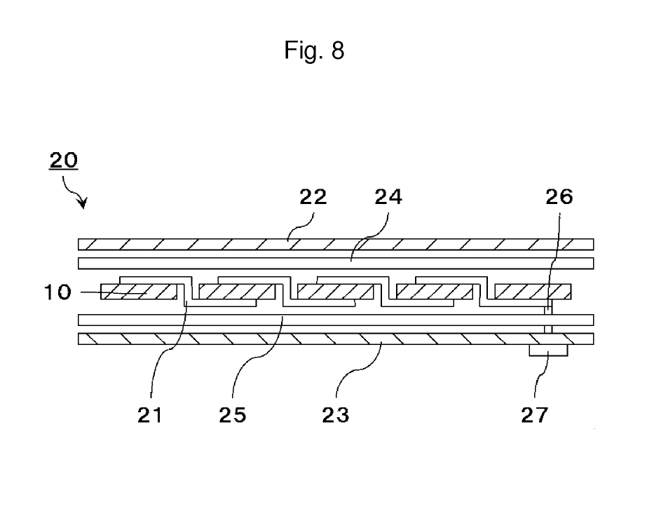

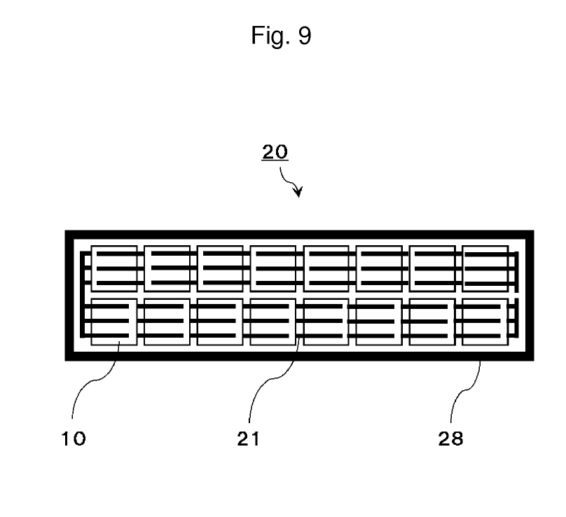

A solar cell module 20 according to an embodiment of the invention will be described in detail with reference to FIGS. 8 and 9.

The solar cell module 20 includes at least one solar cell element 10 of the above-described embodiment. More specifically, in the solar cell module 20, a plurality of the solar cell elements 10 are electrically connected.

In some cases, in which the electric power of the independent solar cell element 10 is low, the solar cell module 20 includes a plurality of solar cell elements 10 connected in series and in parallel. By combining a plurality of the solar cell modules 20, a practical electric power can be extracted.

As illustrated in FIG. 8, the solar cell module 20 includes, for example, a transparent member 22 of glass or the like, a transparent surface filler 24 composed of EVA or the like, a plurality of solar cell elements 10, and wiring members 21 connecting the plurality of solar cell elements 10, a rear filler 25 composed of EVA or the like, and a single-layer or multilayer rear protection member 23 composed of polyethylene terephthalate (PET), polyvinyl fluoride resin (PVF) or the like.

The solar cell elements 10 are electrically connected in series in such a manner that the first electrode 6 of one of two adjacent solar cell elements 10 is connected to the second electrode 7 of the other solar cell element with the wiring member 21.

The wiring member 21 is, for example, a copper foil having a thickness of about 0.1 to 0.2 mm and a width of about 2 mm whose entire surface is coated with a solder material.

The electrodes of the top and end solar cell elements 10 of the plurality of solar cell elements 10 connected in series are connected at one ends of the electrodes to a terminal box 27 acting as a power extraction portion with power extraction wiring lines 26. As illustrated in FIG. 9, although not illustrated in FIG. 8, the solar cell module 20 may further include a frame 28 composed of, for example, aluminum.

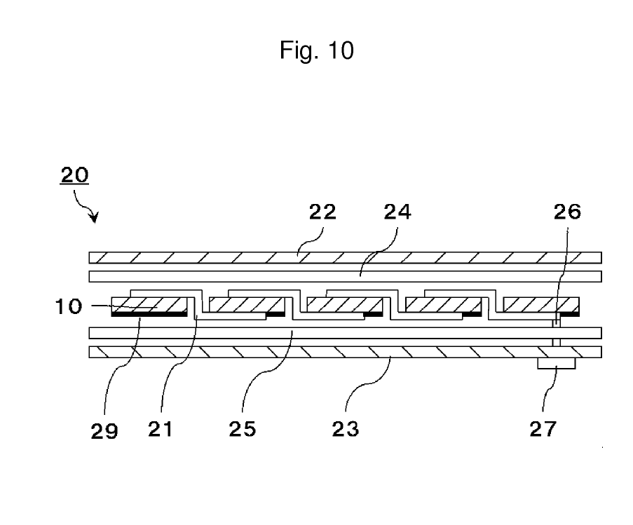

The solar cell module 20 may further include a reflection sheet 29 having a high reflectance on the second surface 10b side of the solar cell elements 10, as illustrated in FIG. 10. In this instance, a high-performance rear reflection structure can be provided. An aluminum (or any other metal) sheet or a white resin sheet (such as acrylic resin sheet, fluorocarbon resin sheet, or polyolefin resin sheet) may be used as the reflection sheet.

Since the solar cell module 20 of the present embodiment includes the solar cell elements 10 each including the passivation layer including the above-described alumina film, the solar cell module 20 has good output power characteristics.

The rear filler 25 and the rear protection member 23 may be composed of a transparent material. Consequently, sunlight reflected from the ground and scattered enters the rear side of the solar cell module 20, and the sunlight is then received at the second surface 10b side of the solar cell elements 10. Thus, the output power characteristics of the solar cell module can be enhanced. In this instance, it is desirable to install the solar cell module 20 in such a manner that the rear side of the solar cell module 20 is not shaded with a rack or the like. In addition, an antireflection layer of a silicon nitride film or the like may be provided over the passivation layer 8. Thus, the output power characteristics of the solar cell module can be further enhanced.

While some embodiments of the present invention have been described, it is to be understood that the invention is not limited the above-described embodiments, and any form may be provided within the scope of the invention.

### EXAMPLES

More specific examples will be described below. First, many polycrystalline silicon substrates of about 200 μm in thickness were prepared as the semiconductor substrates 1. These semiconductor substrates 1 had been doped with boron to impart p-type conductivity.

The first concave-convex shape 1a as illustrated in FIG. 4 was formed in the first surface 10a side of each of the prepared semiconductor substrates 1 by RIE (Reactive Ion Etching).

Subsequently, an n-type second semiconductor layer 3 having a sheet resistance of about 90Ω per square was formed at the surface of the semiconductor substrate 1 by diffusing phosphorus atoms. The second semiconductor layer 3 formed on the second surface 10b side was removed with a fluoronitric acid solution, and then, phosphate glass remaining on the second semiconductor layer 3 was removed with a hydrofluoric acid solution.

Subsequently, an antireflection layer 5 of a silicon nitride film was formed on the first surface 10a side of the semiconductor substrate 1 by plasma CVD. Also, a passivation layer 8 of an alumina film was formed on the second surface 10b side of the semiconductor substrate 1 by repeating the Steps A to D using the ALD apparatus illustrated in FIG. 1. For forming the alumina film, the surface temperature of the semiconductor substrate 1 was controlled to 200° C. Then, an aluminum source material containing trimethylaluminum was supplied for 0.5 second in Step A. In Step B, nitrogen gas was supplied as purge gas for 20 seconds. In Step C, an oxygen source material was supplied for 0.5 second. Furthermore, nitrogen gas was supplied as purge gas for 20 seconds in Step D.

Then, a silver paste was applied in a linear pattern as illustrated in FIG. 2 to the first surface 10a side of the semiconductor substrate 1. Also, an aluminum paste was applied in a pattern of the second collector electrodes 7b as illustrated in FIG. 3 to the second surface 10b side of the semiconductor substrate 1. Furthermore, a silver paste was applied in a pattern of the second power extraction electrode 7a as illustrated in FIG. 3. Then, these paste patterns were fired to form the third semiconductor layer 4, the first electrode 6 and the second electrode 7 as illustrated in FIGS. 2 and 3. The first electrode 6 and the second collector electrodes 7b were each brought into contact with the semiconductor substrate 1 by a fire-through process.

Thus Samples 1 to 4 of the solar cell element were prepared. The production process was different in alumina film forming step among samples as specifically described below.

For Sample 1, first, an alumina film having a thickness of 2 nm was formed in the first forming step of forming an alumina film by supplying H₂O as the oxygen source material to the semiconductor substrate 1, and a second alumina film having a thickness of 28 nm was formed in the second forming step of forming an alumina film on the first alumina film by supplying O₃ as the oxygen source material to the semiconductor substrate 1.

For Sample 2, the semiconductor substrate 1 was pretreated by supplying H₂O to a chamber for 2 seconds before forming an alumina film, and then the alumina film was formed in the same manner as the case of Sample 1.

For Sample 3, an alumina film having a thickness of 30 nm was formed by supplying only H₂O as the oxygen source material to the semiconductor substrate 1.

For Sample 4, an alumina film having a thickness of 30 nm was formed by supplying only O₃ as the oxygen source material to the semiconductor substrate 1.

For each of Samples 1 to 4, the output power characteristics of the solar cell element (short-circuit current lsc, open-circuit voltage Voc, fill factor FF, and photoelectric conversion efficiency) were measured and evaluated. The output power characteristics of these solar cell elements were measured under the conditions of AM (Air Mass) 1.5 and irradiation of 100 mW/cm² in accordance with JIS C 8913.

Table 1 illustrates the measurement results of the output power characteristics of Samples 1 to 4 of the solar cell element, where each result was normalized with the value of Sample 3 that was treated as 100.

TABLE 1

| | | | | photoelectric conversion |
|---|---|---|---|---|
| | Isc * | Voc * | FF * | efficiency * |
| Sample 1 | 101.1 | 101.1 | 99.9 | 102.1 |
| Sample 2 | 102.3 | 101.4 | 100.0 | 103.7 |
| Sample 3 | 100 | 100 | 100 | 100 |
| Sample 4 | 100.6 | 100.3 | 99.9 | 100.8 |

* Normalized to the property of Sample 3, which is treated as 100.

As is clear from Table 1, it was confirmed that Samples 1 and 2, whose alumina films were formed by supplying H₂O and O₃ as the oxygen source material to the semiconductor substrate 1, exhibited higher output power characteristics than Sample 3, whose alumina film was formed by supplying only H₂O as the oxygen source material to the semiconductor substrate 1, and Sample 4, whose alumina film was formed by supplying only O₃ as the oxygen source material to the semiconductor substrate 1.

### REFERENCE SIGNS LIST

1 semiconductor substrate
2 first semiconductor layer
3 second semiconductor layer
4 third semiconductor layer
5 antireflection layer
6 first electrode
6a first power extraction electrode
6b first collector electrode
7 second electrode
7a first layer
7b second layer
8 passivation layer (alumina film)
81 first region
82 second region
9 silicon oxide layer
10 solar cell element
10a first surface
10b second surface
30 ALD apparatus
31 chamber
32 substrate mounting member
33 introduction portion
34 controller
35 supply portion
36 exhaust portion
37 heating portion

1. A method for producing an alumina film, the method comprising:
preparing a substrate; and
forming step of forming an alumina film by supplying an aluminum source material containing aluminum atoms and an oxygen source material containing oxygen atoms comprising H₂O and O₃ to the substrate.

2. The method according to claim 1, wherein step forming the alumina film comprises:
forming a first alumina film by supplying the aluminum source material and the H₂O to the substrate; and
forming a second alumina film on the first alumina film by supplying the aluminum source material and the O₃ to the substrate after forming the first alumina film.

3. The method according to claim 2, wherein forming the first alumina film comprises starting introducing the aluminum source material to the substrate, and then starting introducing the H₂O to the substrate.

4. The method according to claim 2, wherein forming the second alumina film comprises starting introducing the aluminum source material to the substrate, and then starting introducing the O₃ to the substrate.

5. The method according to claim 2, further comprising:
stopping forming the first alumina film when the first alumina film has a first thickness, and
stopping forming the second alumina film when the second alumina film has a second thickness larger than or equal to the first thickness.

6. The method according to claim 1, wherein the oxygen source material comprises a mixed gas of H₂O and O₃.

7. The method according to claim 6, wherein forming the alumina film comprises:
forming a first alumina film with using a first mixed gas having a first ratio R1 which is a mass ratio R defined that mass of the H₂O is divided by mass of the O₃ in the mixed gas, and
forming step of forming a second alumina film on the first alumina film after the third forming step with using a second mixed gas having a second ratio R2 which is a mass ratio R in the mixed gas, the second ratio R2 lower than the first ratio R1.

8. The method according to claim 6, wherein the mass ratio R, which is defined that mass of the H₂O is divided by mass of the O₃, is gradually reduced during forming the alumina film.

9. The method according to claim 1, further comprising forming hydroxide groups on the substrate by supplying H₂O to the substrate before forming the alumina film.

10. The method according to claim 1, wherein the substrate comprises a polycrystalline silicon substrate.

11. A solar cell element comprising an alumina film formed by the method according to claim 1.
